(19) United States
(12) Patent Application Publication
(10) Pub. No.: US 2007/0007634 A1
(43) Pub. Date: Jan. 11, 2007

(54) Method for manufacturing semiconductor chip package

(76) Inventors: Cheul-Joong Youn, Seoul (KR); Sang-Yeop Lee, Cheonan-si (KR); Sang-Hyeop Lee, Cheonan-si (KR)

Correspondence Address: HARNESS, DICKEY & PIERCE, P.L.C., P.O. BOX 8910, RESTON, VA, 20195, US

(21) Appl. No.: 11/516,558

(22) Filed: Sep. 7, 2006

Related U.S. Application Data
(62) Division of application No. 11/001,173, filed on Dec. 2, 2004.

(30) Foreign Application Priority Data
Apr. 29, 2004 (KR) 2004-30089

(51) Int. Cl. H01L 23/495; H01L 21/00

(52) U.S. Cl. 257/676; 438/123; 257/787; 438/124; 257/E23.037

(57) ABSTRACT

A semiconductor chip package may have through holes extending from a chip contact surface of a film type die attaching material to a second surface of a die pad. A resin encapsulant may extend into the through holes to directly contact portions of a semiconductor chip that are superposed over the through holes. The through holes may be formed using a stamping method.

### CROSS REFERENCE TO RELATED APPLICATIONS

This U.S. non-provisional application claims priority under 35 U.S.C. § 119 of Korean Patent Application No. 2004-30089, filed on Apr. 29, 2004, the entire contents of which are incorporated herein by reference.

### BACKGROUND OF THE INVENTION

1. Field of the Invention

The present invention relates to a semiconductor chip package and a method for manufacturing the same.

2. Description of the Related Art

As a result of the development of the semiconductor industry and the demand of users, a trend in electronic products may be towards light-weight and miniaturization. Accordingly, it may be desirable for semiconductor chip packages to be light-weight and miniaturized. In such packages, a bonding strength may be established between a semiconductor chip and a resin encapsulating material. A variance in the bonding strength may result in package defects, such as cracking and/or warpage, for example. Conventional semiconductor chip packages (and their associated shortcomings) are disclosed below.

FIG. 1 is a cross-sectional view of one example of a conventional semiconductor chip package 110. Referring to FIG. 1, the semiconductor chip package 110 may have a die pad 121. A semiconductor chip 111 may be mounted on the die pad 121 using a die attaching material 127. Inner leads 123 may be arranged along the periphery of the die pad 121. Conductive metal wires 131 such as gold wires (for example) may electrically connect together the inner leads 123 and bonding pads 112 of the semiconductor chip 111. A resin encapsulant 135 may seal the semiconductor chip 111, the die pad 121, the inner leads 123 and the conductive metal wires 131. Outer leads 125 may be formed integrally with the inner leads 123. The outer leads 125 may extend from the resin encapsulant 135. The outer leads 125 may be formed suitably for mounting of the semiconductor chip package 110. A plurality of dimples 129 may be formed on a surface of the die pad 121 facing away from the semiconductor chip 111. The resin encapsulant 135 may extend into the dimples 129.

The dimples 129 formed on the surface of the die pad 121 may increase the contact area and the bonding strength between the die pad 121 and the resin encapsulant 135. Thus, the dimples 129 may reduce the occurrence of package defects such as cracking and/or warpage, for example.

However, the dimples 129 may have limitations in improving the bonding strength. Further the dimples 129 may be formed by an etching method, which may be more costly than a stamping method, thereby leading to an increase of manufacturing cost.

FIG. 2A is a cross-sectional view of another example of a conventional semiconductor chip package 210. FIG. 2B is a plan view of the semiconductor chip package 210 of FIG. 2A before a semiconductor chip is mounted. Referring to FIGS. 2A and 2B, the semiconductor chip package 210 may have a die pad 221. A semiconductor chip 211 may be mounted on the die pad 221. Conductive metal wires 231 may connect inner leads 223 to the semiconductor chip 211. In contrast to the package depicted in FIG. 1, the semiconductor chip package 210 may have holes 229 penetrating through the die pad 221. A film type die attaching material 227 may be arranged in an area where the holes 229 are not formed. The semiconductor chip 211 may be attached to the film type die attaching material 227. Outer leads 225 may extend from the inner leads 223. The holes 229 of the die pad 221 may be filled with an epoxy molding compound to form a resin encapsulant 235.

As compared to the dimples 129 depicted in FIG. 1, the holes 229 may allow a larger contact area between the die pad 221 and the resin encapsulant 235. The holes 229 may achieve an anchoring effect, thereby improving the bonding strength between the die pad 221 and the resin encapsulant 235.

However, it may be difficult to achieve registration between the film type die attaching material 227 and the die pad 221. In particular, it may be difficult to provide the film type die attaching material 227 between the holes 229, as shown in FIG. 2B. Further, the semiconductor chip 211 attached to the die pad 221 may be damaged during molding and curing processes for forming the resin encapsulant 235.

FIG. 3 is a cross-sectional view of another example of a conventional semiconductor chip package 310. Referring to FIG. 3, the semiconductor chip package 310 may have a die pad 321. A semiconductor chip 311 may be mounted on the die pad 321. Conductive metal wires 331 may connect the semiconductor chip 311 to inner leads 323. In contrast to the packages depicted in FIGS. 1 and 2, holes 329 may be formed through the die pad 321 and a film type die attaching material 327 may be provided on the die pad 321 so as to cover the holes 329. A resin encapsulant 335 may extend into the holes 329.

As compared to the dimples 129 depicted in FIG. 1, the holes 329 may provide a larger contact area between the die pad 321 and the resin encapsulant 335. Further, an entire surface of the semiconductor chip 311 may be in contact with the film type die attaching material 327. Thus, as compared to the package depicted in FIG. 2, the semiconductor chip 311 attached to the die pad 321 may be less likely to be damaged during molding and curing processes for forming the resin encapsulant 335.

However, a portion of the film type die attaching material 327 may be exposed through the holes 329 of the die pad 321. These exposed portions of the film type die attaching material 327 may directly contact the resin encapsulant 335. The bonding strength may be relatively weak between the film type die attaching material 327 and an epoxy molding compound of the resin encapsulant 335.This relatively weak bonding strength may increase the likelihood of the package 310 experiencing moisture absorption (and/or other defects), thereby adversely affecting reliability and package quality, for example.

### SUMMARY OF THE INVENTION

Exemplary, non-limiting embodiments of the present invention are directed to a semiconductor chip package and a method for manufacturing the same, in which a contact area between a semiconductor chip and a resin encapsulant may be increased, while a contact area between a resin encapsulant and a film type die attaching material may be reduced, thereby reducing the likelihood of package damage that may occur due to moisture absorption, for example.

In an example embodiment, the semiconductor chip package may include a semiconductor chip and a die pad having a first surface and a second surface. Leads may be electrically connected to the semiconductor chip, and a resin encapsulant may seal the semiconductor chip, the die pad, and a portion of the leads. The semiconductor chip may be mounted on the first surface of the die pad via a film type die attaching material. Through holes may extend from a surface of the film type die attaching material in contact with the semiconductor chip to the second surface of the die pad. The resin encapsulant may extend into the through holes and directly contact portions of the semiconductor chip superposed over the through holes.

The through holes may be perpendicular to major surfaces of the film type die attaching material and the die pad. The through holes may be formed by a stamping method. The film type die attaching material may include a single adhesive layer, or a two-sided adhesive tape having a base film and adhesive layers formed on both sides of the base film. The through holes may have at least one shape selected from an oval column or a multi-sided column.

In another example embodiment, a method for manufacturing a semiconductor chip package may involve preparing a leadframe. The leadframe may include a die pad having a first surface and a second surface opposite to the first surface, and leads arranged along the periphery of the die pad and spaced apart from the die pad. A film type die attaching material may be provided on the first surface of the die pad. The film type die attaching material may have a chip contact surface facing away from the first surface of the die pad. Through holes may be formed that extend from the chip contact surface of the film type die attaching material to the second surface of the die pad. A semiconductor chip may be provided on the film type die attaching material. The semiconductor chip may be electrically connected to the leads using conductive metal wires. A resin encapsulant may be formed to seal the semiconductor chip, the die pad, the conductive metal wires and a portion of the leads. The resin encapsulant may extend into the through holes to directly contact portions of the semiconductor chip superposed over the through holes.

Forming the through holes may involve stamping the film type die attaching material and the die pad. The through holes may be perpendicular to major surfaces of the film type die attaching material and the die pad.

The film type die attaching material may be a single layered film type die attaching material. The film type die attaching material may be a two-sided adhesive tape.

The through holes may have at least one shape selected from an oval column and a multi-sided column.

In an example embodiment, a package may include a die pad. An attaching material may be provided on the die pad. A semiconductor chip may be provided on the attaching material. At least one hole may extend through the attaching material and the die pad. The at least one hole may have an opening in a surface of the attaching material in contact with the semiconductor chip.

In an example embodiment, a method for manufacturing a package may involve providing a die pad. An attaching material may be provided on the die pad. A portion of the attaching material and a portion of the die pad may be removed to form at least one hole through the attaching material and the die pad. A semiconductor chip may be provided on the attaching material.

### BRIEF DESCRIPTION OF THE DRAWINGS

Exemplary embodiments of the present invention will be readily understood with reference to the following detailed description thereof provided in conjunction with the accompanying drawings, wherein like reference numerals designate like structural elements.

FIG. 1 is a cross-sectional view of an example of a conventional semiconductor chip package.

FIG. 2A is a cross-sectional view of another example of a conventional semiconductor chip package.

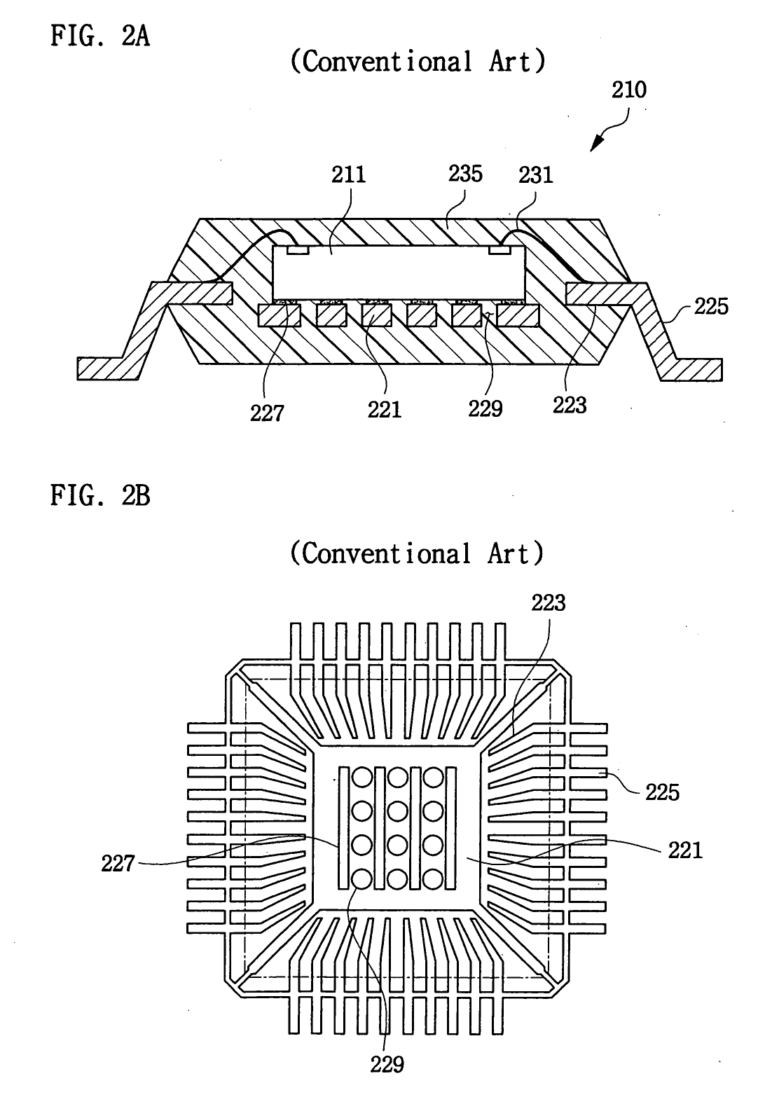

FIG. 2B is a plan view of a semiconductor chip package of FIG. 2A before a chip is mounted.

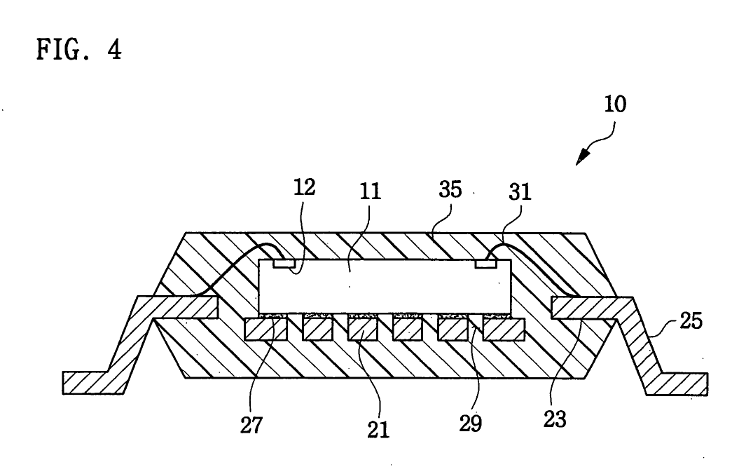

FIG. 3 is a cross-sectional view of another example of a conventional semiconductor chip package.

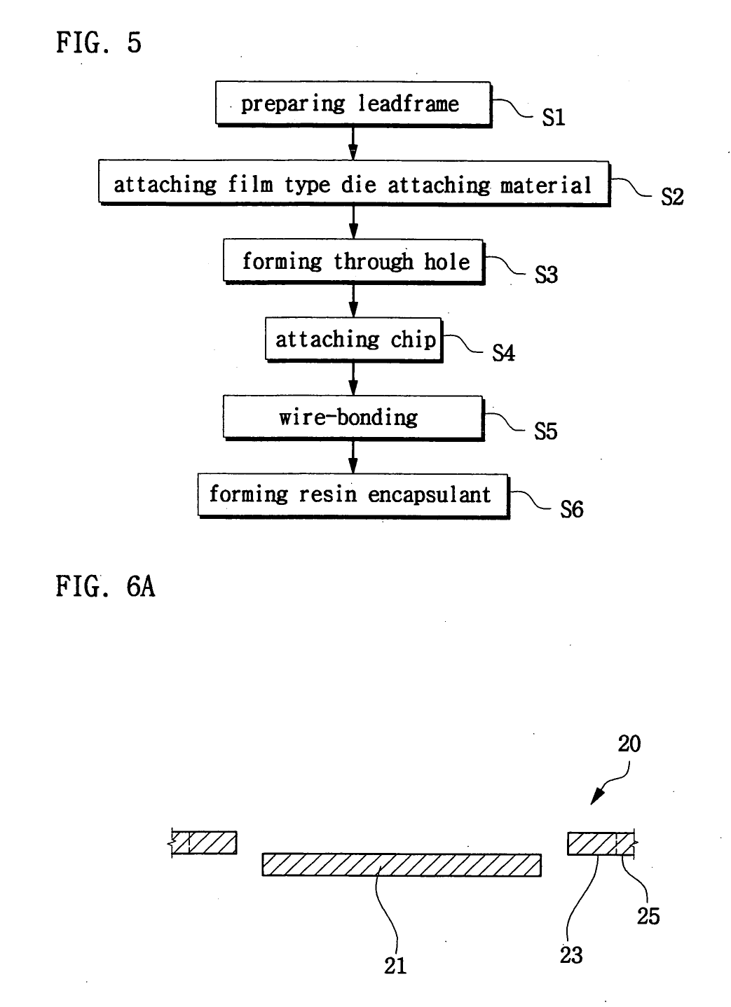

FIG. 4 is a cross-sectional view of a semiconductor chip package in accordance with an exemplary, non-limiting embodiment of the present invention.

FIG. 5 is a block diagram of a method for manufacturing a semiconductor chip package in accordance with an exemplary, non-limiting embodiment of the present invention.

FIGS. 6A through 6G are cross-sectional views of a method for manufacturing a semiconductor chip package in accordance with an exemplary, non-limiting embodiment of the present invention.

### DETAILED DESCRIPTION OF THE EXEMPLARY EMBODIMENTS

The present invention will now be described more fully with reference to the accompanying drawings, in which exemplary embodiments of the invention are illustrated. It will be appreciated that the invention may be embodied in many different forms and should not be construed as limited to the particular embodiments set forth herein. Rather, the disclosed embodiments are provided so that this disclosure will be thorough and complete, and will fully convey the scope of the invention to those skilled in the art.

In the description, well-known structures and processes have not been described or illustrated in detail to avoid obscuring the present invention. It will be appreciated that for simplicity and clarity of illustration, some elements illustrated in the figures may not be drawn to scale. For example, the dimensions of some of the elements may be exaggerated or reduced relative to other elements for clarity. Also, a layer may be considered as being formed “on” another layer or a substrate when formed either directly on the referenced layer or the substrate or formed on other layers or patterns overlaying the referenced layer or substrate.

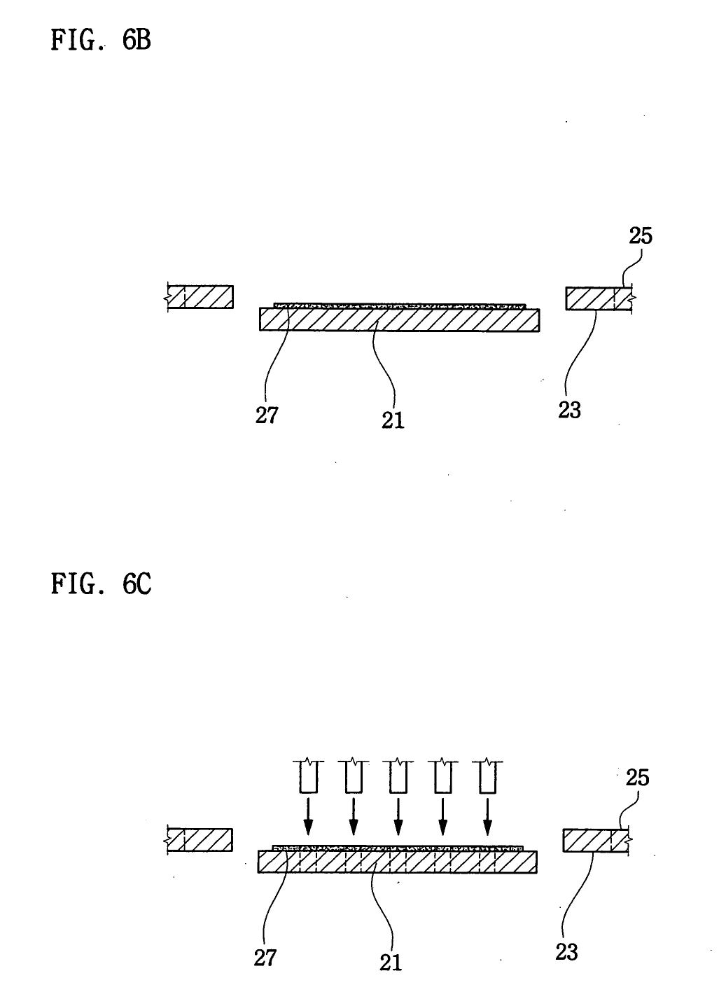

FIG. 4 is a cross-sectional view of a semiconductor chip package 10 in accordance with an exemplary, non-limiting embodiment of the present invention. Referring to FIG. 4, the semiconductor chip package 10 may include a die pad 21 having a first surface including a chip mounting area and a second surface opposite to the first surface. A semiconductor chip 11 may be mounted on the first surface of the die pad 21. The semiconductor chip may be of an edge pad type; i.e., bonding pads 12 may be arranged along edges of the semiconductor chip 11. A plurality of inner leads 23 may be arranged along the periphery of the die pad 21. The bonding pads 12 of the semiconductor chip 11 may be wire-bonded to corresponding inner leads 23 by conductive metal wires 31. The semiconductor chip 11, the die pad 21, the inner leads 23 and the conductive metal wires 31 may be sealed with a resin encapsulant 35. Outer leads 25 may be formed integrally with the inner leads 23. The outer leads 25 may extend from the resin encapsulant 35. The outer leads 25 may be formed suitably for mounting of the semiconductor chip package 10.

A plurality of through holes 29 may be provided through the die pad 21 and a film type die attaching material 27. Specifically, at least one of the through holes 29 may extend from an opening provided in a surface of the film type die attaching material 27 in contact with the semiconductor chip 11 to an opening in the second surface of the die pad 21. The die attaching material 27 may define a longitudinal portion of each through hole 29. That is, a side wall of the die attaching material 27 may extend all the way around the periphery of the through hole 29. The die pad 21 may define another, different longitudinal portion of each through hole 29. That is, a side wall of the die pad 21 may extend all the way around the periphery of the through hole 29.

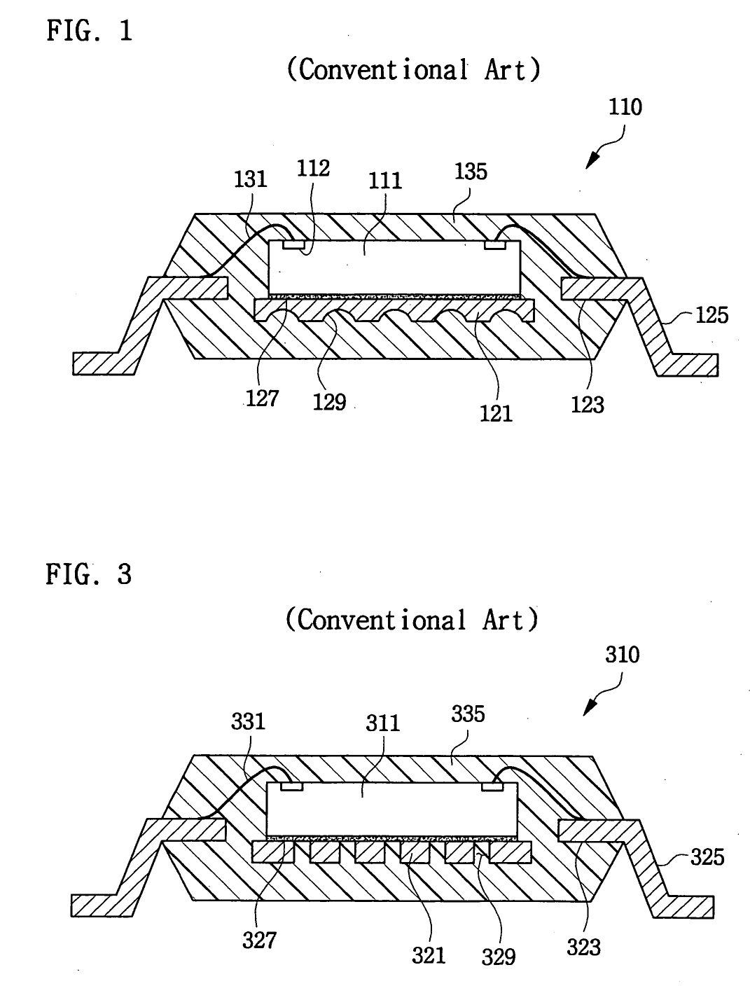

In the example embodiment depicted in FIG. 1, at least one of the through holes 29 may have a columnar shape and may extend perpendicular to major surfaces of the die pad 21 and the die attaching material 27. However, the invention is not limited in this regard. For example, the through holes 29 may extend at desired angles relative to the major surfaces of the die pad 21 and the die attaching material 27. In a given semiconductor chip package 10, the respective extend angles may be the same or different from one through hole to the next. Moreover, the extend angle of a particular through hole may vary along the length of the through hole. The through holes 29 may not be limited to a columnar shape having a particular transverse profile. For example, the columnar shape may have a transverse profile (i.e., taken along a plane perpendicular to the longitudinal axis of the through hole 29) in the shape of a circle, an oval, a triangle, a square, a rectangle, or some other polygon. Along the length of a particular through hole, the transverse profiles may be uniformly shaped (as shown in FIG. 4) or have varied shapes. For example, the through hole 29 may be tapered along its length, and/or have a first transverse profile proximate the semiconductor chip and a second, different profile remote from the semiconductor chip. In a given semiconductor chip package 10, the through holes 29 may be of the same shape, or varied shapes.

The semiconductor chip 11 may be provided on the first surface of the die pad 21 using the film type die attaching material 27. One surface of the semiconductor chip 11 may be connected to the die pad 21, except for those portions of the surface superposed over the through holes 29. The resin encapsulant 35 may be fabricated from a resin encapsulating material such as an epoxy molding compound, for example. Other encapsulating materials may be suitably implemented as is well known in this art. The resin encapsulant 35 may extend into the through holes 29 and may contact with the exposed portion of the semiconductor chip 11.

The die attaching material 27 may be a single layered film type die attaching material. But the invention is not limited in this regard. For example, the film type die attaching material 27 may be a two-sided adhesive tape having a base film and adhesive layers formed on both sides of the base film. Other suitable die attaching materials may be suitably implemented as is well known in this art.

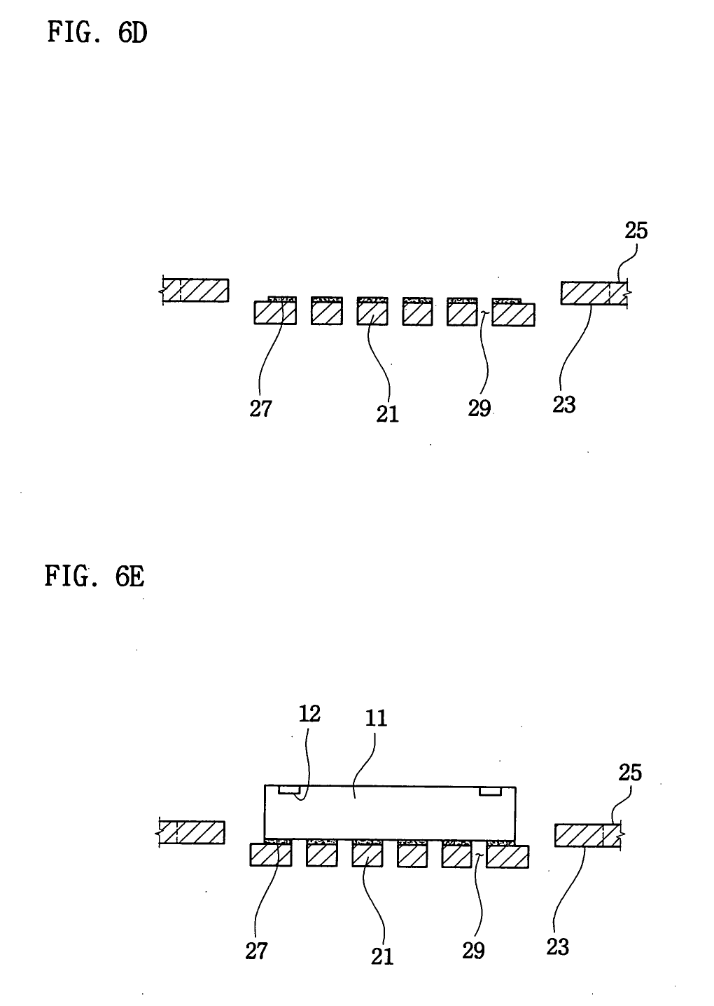

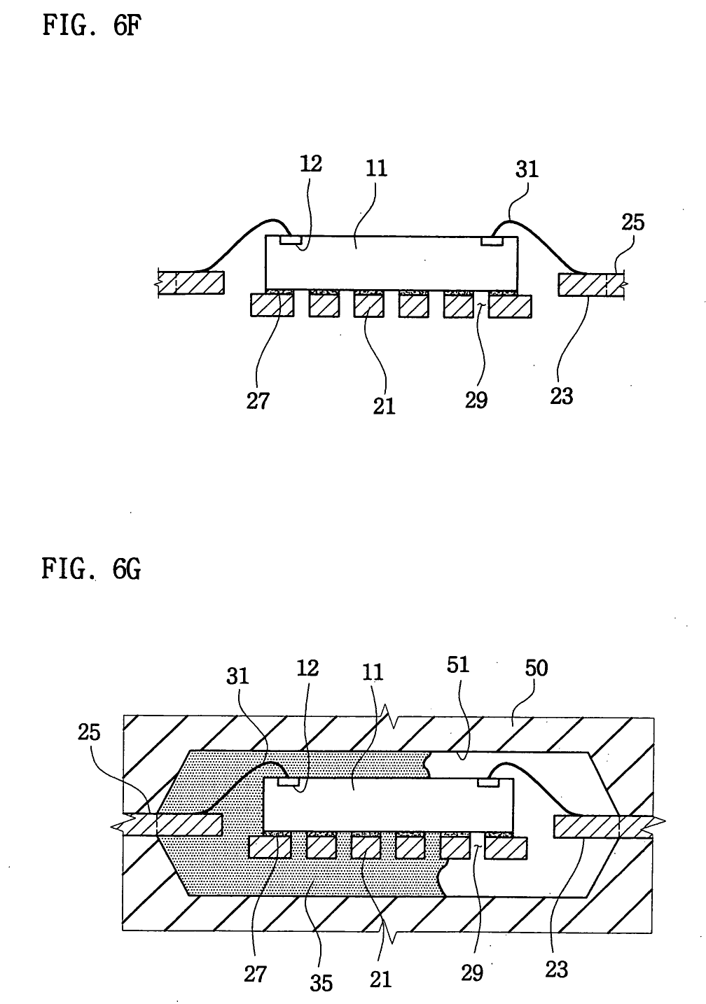

FIG. 5 is a block diagram of a method that may be implemented to manufacture a semiconductor chip package in accordance with an exemplary, non-limiting embodiment of the present invention. FIGS. 6A through 6G are cross-sectional views of the semiconductor chip package at intermediate stages of a method for manufacturing a semiconductor chip package.

With reference to FIG. 5, the method for manufacturing a semiconductor chip package may involve preparing a leadframe including a die pad (S1), attaching a film type die attaching material to the die pad (S2), forming through holes in the film type die attaching material and the die pad (S3), attaching a chip to the die pad (S4), wire bonding the semiconductor chip to the leads (S5), and forming a resin encapsulant (S6).

Referring to FIG. 6A, a leadframe 20 may be prepared. The leadframe 20 may include a die pad 21, a plurality of inner leads 23, and a plurality of outer leads 25. The die pad 21 may have a first surface and a second surface opposite to the first surface. The inner leads 23 may be arranged along the periphery of the die pad 21 and the outer leads 25 may be formed integrally with the inner leads 23.

Referring to FIG. 6B, a film type die attaching material 27 may be provided on the first surface of the die pad 21. The film type die attaching material 27 may be a single layered film type die attaching material. The film type die attaching material 27 may also include a two-sided adhesive tape or a UV adhesive tape. Other die attaching materials may be suitably implemented as is well known in this art.

Referring to FIGS. 6C and 6D, a plurality of through holes 29 may be formed in the die attaching material and the die pad 21. The through holes 29 may extend from a chip contact surface of the film type die attaching material 27 to the second surface of the die pad 21. The through holes 29 may have a columnar shape. The through holes 29 may be formed using numerous and varied methods such as etching, stamping, drilling, mechanical cutting, laser cutting, and sawing methods, for example. The invention is not limited to a specific through hole forming method and other alternative methods may be suitably implemented. The stamping method may be preferred in terms of cost and/or productivity. The shape of the through holes may depend on the technique used to form the through holes.

Referring to FIG. 6E, a semiconductor chip 11 may be attached to the film type die attaching material 27 on the die pad 21. The semiconductor chip 11 may be an edge pad type semiconductor chip. That is, bonding pads 12 may be arranged along the edges of an active surface of the semiconductor chip 11. The invention is not, however, limited in this regard. For example, the semiconductor chip 11 may be a center pad type semiconductor chip, or some other alternative type semiconductor chip that may be well known in this art.

Referring to FIG. 6F, a wire bonding may be performed. Here, the bonding pads 12 of the semiconductor chip 11 may be connected to corresponding inner leads 23 using conductive metal wires 31, for example.

Referring to FIG. 4 and 6G, a resin encapsulant 35 may be formed. The resin encapsulant 35 may be formed using a mold 50 having a cavity 51. The resin encapsulant 35 may seal the semiconductor chip 11, the die pad 21, the inner leads 23, and the conductive metal wires 31 to mechanically and chemically protect these component parts from the external environment.

The outer leads 25, which may be formed integrally with the inner leads 23, may extend from the resin encapsulant 35.

A semiconductor chip package and a method for manufacturing the same in accordance with exemplary, non-limiting embodiments of the present invention may have through holes extending through a die pad, as well as through a film type die attaching material. In this way, the contact area between the resin encapsulant and the film type die attaching material may be reduced. A resin encapsulant may extend into the through holes so that anchoring effect may be obtained, thereby improving the bonding strength between the resin encapsulant and the semiconductor chip. In this way, the semiconductor chip package may be less likely to experience damage that may occur due to moisture absorption, thereby improving reliability of the semiconductor chip package. The through holes may be formed using a stamping method, for example, leading to reduced manufacturing cost.

Although exemplary embodiments of the present invention have been described in detail hereinabove, it should be understood that many variations and/or modifications of the basic inventive concepts, which may appear to those skilled in the art, will still fall within the spirit and scope of the exemplary embodiments of the present invention as defined in the appended claims.

1.-7. (canceled)

8. A method for manufacturing a semiconductor chip package comprising:
preparing a leadframe having a die pad and leads, the die pad having a first surface and a second surface opposite to the first surface, and the leads arranged along the periphery of the die pad and spaced apart from the die pad;
providing a film type die attaching material on the first surface of the die pad, the film type die attaching material having a chip contact surface facing away from the first surface of the die pad;
forming through holes that extend from the chip contact surface of the film type die attaching material to the second surface of the die pad;
providing a semiconductor chip on the chip contact surface of the film type die attaching material;
wire-bonding the semiconductor chip to the leads using conductive metal wires; and
sealing the semiconductor chip, the die pad, the conductive metal wires and a portion of the leads to form a resin encapsulant so that the resin encapsulant extends into the through holes to directly contact portions of the semiconductor chip superposed over the through holes.

9. The method of claim 8, wherein forming the through holes includes stamping the film type die attaching material and the die pad.

10. The method of claim 8, wherein the through holes are formed perpendicular to major surfaces of the film type die attaching material and the die pad.

11. The method of claim 8, wherein the film type die attaching material is a single layered film type die attaching material.

12. The method of claim 8, wherein the film type die attaching material is a two-sided adhesive tape having a base film and adhesive layers formed on both sides of the base film.

13. The method of claim 8, wherein the through holes have at least one shape selected from an oval column and a multi-sided column.

14.-17. (canceled)

18. A method for manufacturing a package, the method comprising:
providing a die pad;
providing an attaching material on the die pad;
removing a portion of the attaching material and a portion of the die pad to form at least one hole through the attaching material and the die pad; and
providing a semiconductor chip on the attaching material.

19. The method of claim 18, wherein the removing is performed via one stroke of a stamping process.

20. A package manufactured in accordance with the method of claim 18.

21. A package manufactured in accordance with the method of claim 8.
